(19) United States
(12) Patent Application Publication
(10) Pub. No.: US 2016/0194542 A1
(43) Pub. Date: Jul. 7, 2016

(54) POLYIMIDE RESIN COMPOSITION, AND HEAT-CONDUCTIVE ADHESIVE FILM PRODUCED USING SAME

(71) Applicant: NIPPON KAYAKU KABUSHIKI KAISHA, Chiyoda-ku, Tokyo (JP)

(72) Inventors: Kenji SEKINE, Tokyo (JP); Noriyuki NAGASHIMA, Tokyo (JP); Kazunori ISHIKAWA, Tokyo (JP)

(73) Assignee: NIPPON KAYAKU KABUSHIKI KAISHA, Tokyo (JP)

(21) Appl. No.: 14/911,290

(22) PCT Filed: May 30, 2014
(86) PCT No.: PCT/JP2014/064393

§ 371 Date: Feb. 10, 2016

(30) Foreign Application Priority Data
Oct. 23, 2013 (JP) 2013-219912

(51) Int. Cl. C09K 5/14; H05K 7/20; C09D 163/00; C09J 163/00; C09D 179/08; C09J 179/08

(52) U.S. Cl. CPC C09K 5/14; C09D 179/08; C09J 179/08; C09D 163/00; C09J 163/00; H05K 7/2089

(57) ABSTRACT

A polyimide resin composition which produces a heat-conductive adhesive film having specifically satisfactory electrical insulation properties and thermal conductivity, exhibiting adhesiveness at a low temperature of about 170° C. to 200° C., and exhibiting a glass transition temperature of higher than 200° C. after lamination of the film, is provided. Disclosed is a resin composition including an aromatic polyimide resin (A) containing phenolic hydroxyl groups; a filler (B); and an epoxy resin (C) having a melt viscosity of 0.04 Pa·s or less, wherein the ratio of the amounts in parts by mass of the polyimide resin (A), the filler (B), and the epoxy resin (C) satisfies the relationships: (A):(C)=99:1 to 1:99, and ((A)+(C)):(B)=80:20 to 5:95.

### TECHNICAL FIELD

The present invention relates to a resin composition including a phenolic hydroxyl group-containing aromatic polyimide resin and an epoxy resin having a melt viscosity of 0.04 Pa·s or less, the resin composition being suitably usable particularly for a silicon carbide-based power module where heat resistance, high heat, dissipation properties and sufficient, insulation properties are required, when the resin composition is used to produce a heat-conductive adhesive film, as well as to a heat-conductive adhesive film using the resin composition, a laminate having a cured layer of the resin composition, and an electronic component.

### BACKGROUND ART

In recent years, semiconductor integrated circuits are used in various electronic devices. Among them, for those devices that need large electric power, power modules having power elements such as a high-power diode, a transistor and an IC mounted therein are used. A power-module is required to have sufficient heat dissipation properties for dissipating the heat generated from power-elements, and high electrical insulation properties (electrical reliability) at a high temperature.

For the purpose of bonding a power module with a heat dissipation plate, that, is, a heat transfer member for dissipating heat in order to allow the power module to have sufficient heat, dissipation properties, various heat-conductive adhesive films are used. In these heat-conductive films, metals, alloys or compounds having high thermal conductivity, such as silver, copper, gold and aluminum; electrically insulating ceramics such as aluminum oxide, silicon nitride and silicon carbide; or particulate-shaped or fiber-shaped thermally conductive filler-materials such as carbon black, graphite and diamond are incorporated in order to increase thermal conduction properties. Among them, electrically insulating, heat-conductive adhesive films filled with boron nitride, aluminum oxide, aluminum nitride, silica or the like, which have excellent thermal conduction properties and electrical insulation properties, have been extensively put to practical use.

Many resin compositions each including a heat-resistant resin such as polyimide and a heat-conductive filler have been suggested so as to obtain the heat-conductive adhesive films described above. Particularly, since a resin composition including a polyimide containing an ether bond in the skeleton and a heat-conductive inorganic filler can be designed to have a low glass transition temperature, it is known that when a film is produced using this resin composition, the film can be adhered to an adherend at a low temperature of about 170° C. to 200° C., and the film can be suitably used as a heat-conductive adhesive film (Patent Literature 1).

In recent years, silicon carbide power semiconductor that enables size reduction, reduced electric power consumption, and efficiency increase compared to silicon semiconductor, and exhibits reduced switching loss and excellent operation characteristics in a high temperature environment, is expected as a next-generation low loss power element. In a case in which a silicon carbide-based power module is produced using silicon carbide power semiconductor, since the temperature range at which peripheral members are used increases up to near 200° C., a cured layer after adhesion is required to have heat resistance of 200° C. or higher.

However, according to Patent Literature 1, since the glass transition temperature of the cured film after adhesive lamination is below 200° C., the cured film cannot be used as a heat-conductive adhesive film that is used to be adhered to a silicon carbide-based power module.

On the other hand, regarding a resin composition including a phenolic hydroxyl group-containing aromatic polyamide resin and a heat-conductive inorganic filler, when a film is produced using this resin composition, the film can be adhered to an adherend at a low temperature of about 170° C. to 200° C., and the glass transition temperature of the cured film after adhesive lamination is above 200° C. Therefore, the resin composition has potential for application to silicon carbide-based power modules (Patent Literature 2). However, as the level of required characteristics is ever increasing in recent years, high electrical insulation properties (for example, about 6 kV or higher) and thermal conduction properties (for example, 10 W/m·K or higher) are required; however, sufficient electrical insulation properties and thermal conduction properties are not obtained with this resin composition.

On the other hand, a resin composition of an epoxy resin and an aromatic polyimide resin containing ether bonds in the skeleton and containing phenolic hydroxyl groups is known (Patent Literature 3). Regarding this resin composition, there are no limitations on the epoxy resin used therein, and in the Examples, an epoxy resin having a melt viscosity of higher than 0.04 Pa·s was used. The resin composition is intended to be used as a binder for non-aqueous battery electrodes, and the use of the resin composition for silicon carbide-based power modules is not known.

### CITATION LIST

### Patent Literatures

Patent Literature 1: WO 2011/001698 A

Patent Literature 2: WO 2011/114665 A

Patent Literature 3: JP 2011-124175 A

### SUMMARY OF INVENTION

### Technical Problem

An object of the present invention is to provide a resin composition including an aromatic polyimide resin containing phenolic hydroxyl groups, an epoxy resin, and a heat-conductive inorganic filler, the resin composition being capable of producing a heat-conductive adhesive film which exhibits specifically satisfactory adhesiveness at a low temperature (about 170° C. to 200° C.) (for example, about 6 N/cm), electrical insulation properties (for example, about 6 kV or higher), and thermal conductivity (for example, 10 W/m·K or higher), and the resin composition exhibiting satisfactory heat resistance (for example, a glass transition temperature of 200° C. or higher) after being cured.

### Solution to Problem

The inventors of the present invention conducted a thorough investigation in order to solve the problems described above, and as a result, the inventors found that when a resin composition including an aromatic polyimide resin containing phenolic hydroxyl groups, an epoxy resin having a melt viscosity of 0.04 Pa·s or less, and an inorganic filler, particularly a heat-conductive inorganic filler, is used, the object of the invention may be achieved.

That is, the present invention relates to:

(1) A resin composition including an aromatic polyimide resin (A) containing phenolic hydroxyl groups; a filler (B); and an epoxy resin (C) having a melt viscosity of 0.04 Pa·s or less, wherein the ratio of the amounts in parts by mass of the polyimide resin (A), the filler (B), and the epoxy resin (C) satisfies the relationships: (A):(C)=99:1 to 1:99 and ((A)+(C)):(B)=80:20 to 5:95.
(2) The resin composition according to (1), wherein the aromatic polyimide resin (A) containing phenolic hydroxyl groups is a phenolic hydroxyl group-containing aromatic polyimide resin (A) having a repeating unit represented by the following Formula (1) in the structure:

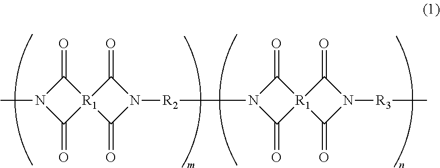

wherein m and n are average values and represent positive numbers that satisfy the relationships: 0.005<n/(m+n)<0.14 and 0<m+n<200; R₁ represents a tetravalent aromatic group having an ether bond but not having a phenolic hydroxyl group; R₂ represents a divalent aromatic group containing an ether bond but not having a phenolic hydroxyl group; and R₃ represents a divalent aromatic group having a phenolic hydroxyl group.
(3) The resin composition according to (2), wherein in the repeating unit represented by Formula (1),

R₁ represents a tetravalent aromatic group represented by the following Formula (2):

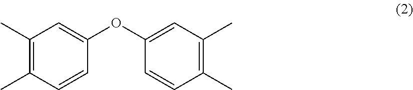

R₂ represents a divalent aromatic group represented by the following Formula (3):

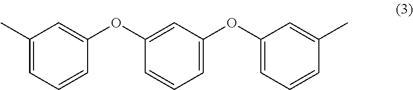

and R₃ represents one or more divalent aromatic groups selected from the following Formula (4):

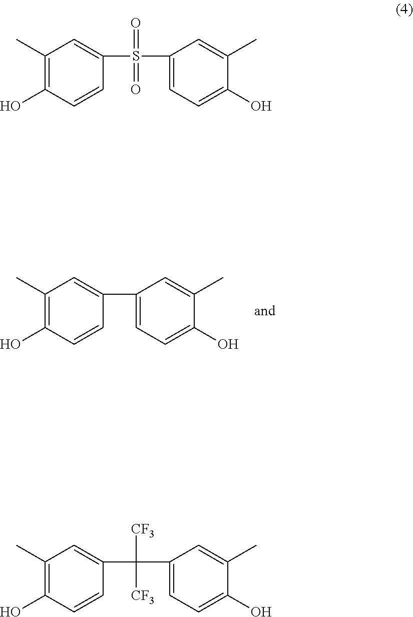 [SMILES: Cc1cc(S(=O)(=O)c2ccc(O)c(C)c2)ccc1O ; Cc1cc(-c2ccc(O)c(C)c2)ccc1O ; Cc1cc(C(c2ccc(O)c(C)c2)(C(F)(F)F)C(F)(F)F)ccc1O]

(4) The resin composition according to any one of (1) to (3), wherein the filler (B) is at least one selected from aluminum nitride and boron nitride.
(5) A varnish including the resin composition according to any one of (1) to (4) dissolved in an organic solvent.
(6) A heat-conductive adhesive film including the resin composition according to any one of (1) to (4).
(7) A laminate including the heat-conductive adhesive film according to (6) and a copper foil, an aluminum foil or a stainless steel foil.
(8) A laminate including the heat-conductive adhesive film according to (6) and a heat dissipation plate.
(9) A laminate including a cured layer of the resin composition according to any one of (1) to (4) and a copper foil, an aluminum foil or a stainless steel foil.
(10) A laminate including a cured layer of the resin composition according to any one of (1) to (4) and a heat dissipation plate.
(11) An electronic component including a cured layer of the resin composition according to any one of (1) to (4).
(12) The electronic component according to (11), wherein the cured layer of the resin composition exists between a power module and a cooler in a state of being in contact with both of the elements.
(13) The electronic component, according to (12), wherein the power module is a silicon carbide-based power module.
(14) A phenolic hydroxyl group-containing aromatic polyimide resin (A′) including in the structure a repeating unit represented by the following Formula (9):

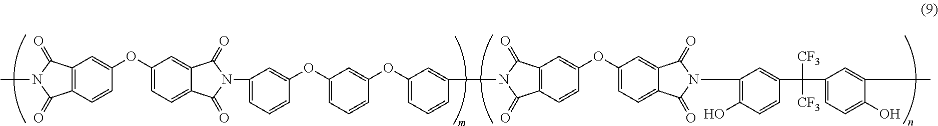

or Formula (10):

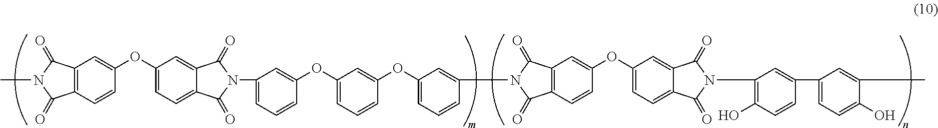

wherein m and n are average values and represent positive numbers satisfying the relationships: 0.005<n/(m+n)<0.14 and 0<m+n<200.

### Advantageous Effects of Invention

The present resin composition is such that when a film is produced using this resin composition, the film can be adhered to an adherend at a low temperature of about 170° C. to 200° C., and the glass transition temperature of the cured layer after adhesive lamination is above 200° C. Furthermore, since the film exhibits specifically satisfactory electrical insulation properties and high thermal conductivity (heat dissipation properties), the film is suitable as a heat-conductive adhesive film for a silicon carbide-based power module. Furthermore, a varnish containing the present resin composition is also preferably used in other applications where heat, dissipation properties (thermal conduction properties) are required, for example, in an application in which the varnish is used as a heat-conductive, heat-resistant coating material by impregnating a coil used in a power device such as a motor, with the varnish and drying the varnish, or in an application of an electrically conductive bonding material (application as a substitute of solder bonding) between a circuit wiring and an electronic component in a process for mounting electronic components.

### DESCRIPTION OF EMBODIMENTS

It is preferable that the phenolic hydroxyl group-containing aromatic polyimide resin (A) included in the present resin composition contains ether bonds in the skeleton, and it is more preferable that the ether bonds are bonded at the meta-position of an aromatic ring. Specifically, a phenolic hydroxyl group-containing aromatic polyimide resin having a repeating unit represented by the following Formula (1) in the structure is more suitable:

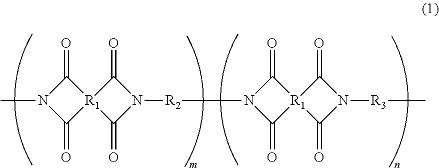

wherein m and n are average values and represent positive numbers that satisfy the relationships: 0.005<n/(m+n)<0.14 and 0<m+n<200; R₁ represents a tetravalent aromatic group that has an ether bond but does not have a phenolic hydroxyl group; R₂ represents a divalent aromatic group that contains an ether bond but does not have a phenolic hydroxyl group; and R₃ represents a divalent aromatic group having a phenolic hydroxyl group.

This resin is usually obtained by obtaining polyamic acid through an addition reaction between a tetracarboxylic acid dianhydride represented by the following Formula (5):

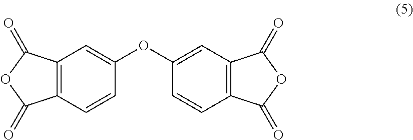 [SMILES: O=C1OC(=O)c2cc(Oc3ccc4c(c3)C(=O)OC4=O)ccc21]

and a diamine compound represented by the following Formula (6) that contains an ether bond but does not have a phenolic hydroxyl group:

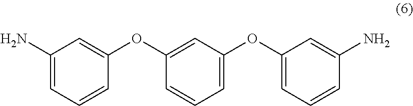 [SMILES: Nc1cccc(Oc2cccc(Oc3cccc(N)c3)c2)c1]

as well as one or more diaminodiphenol compound selected from the following Formula (7):

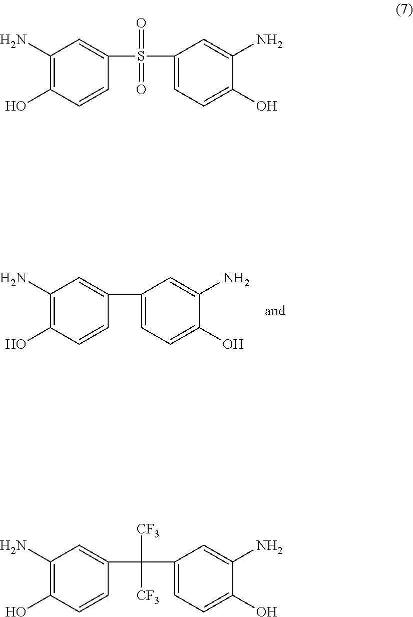 [SMILES: Nc1cc(S(=O)(=O)c2ccc(O)c(N)c2)ccc1O ; Nc1cc(-c2ccc(O)c(N)c2)ccc1O ; Nc1cc(C(c2ccc(O)c(N)c2)(C(F)(F)F)C(F)(F)F)ccc1O]

and further subjecting the polyamic acid to a dehydration-ring closure reaction. It is preferable that this series of reactions are carried out in one pot.

Through the processes described above, a phenolic hydroxyl group-containing aromatic polyimide resin (A) having, in the structure, a repeating unit represented by the above Formula (1), in which R₁ represents a tetravalent aromatic group represented by the following Formula (2):

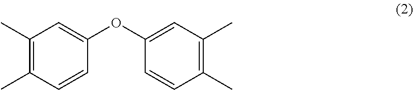

R₂ represents a divalent aromatic group represented by the following Formula (3):

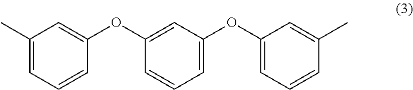

and R₃ represents one or more divalent aromatic groups selected from the following Formula (4):

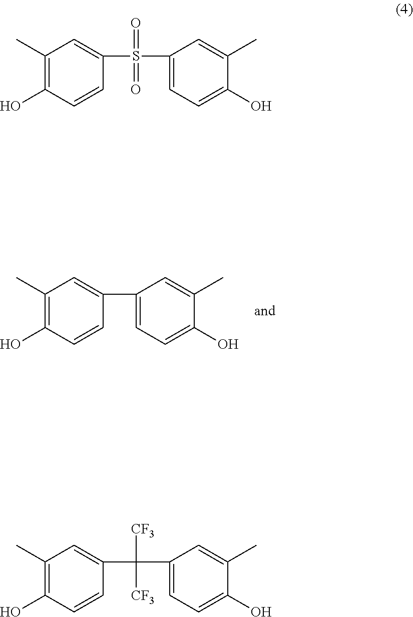 [SMILES: Cc1cc(S(=O)(=O)c2ccc(O)c(C)c2)ccc1O ; Cc1cc(-c2ccc(O)c(C)c2)ccc1O ; Cc1cc(C(c2ccc(O)c(C)c2)(C(F)(F)F)C(F)(F)F)ccc1O]

is obtained.

It is preferable that the molar ratio between the diamine compound and the diaminodiphenol compound used in the reaction described above, that is, the values of m and n satisfy the following: 0.005<n/(m+n)<0.14 and 0<m+n<200. When the values of m and n are in the ranges described above, the hydroxyl group equivalent of the phenolic hydroxyl group derived from the aromatic group R₃ one molecule of the polyimide resin (A), and the molecular weight have appropriate values for exhibiting the effects of the present invention. It is more preferable the relationship: 0.01<n/(m+n)<0.06 is satisfied, and it is even more preferable that the relationship: 0.015<n/(m+n)<0.04. If 0.005> n/(m+n), the glass transition temperature of the cured film after adhesion is below 200° C., which is not preferable. If n/(m+n)> 0.14, electrical insulation properties are deteriorated, and this is not preferable.

Regarding the average molecular weights of the present polyimide resin (A), it is preferable that the number average molecular weight is 1,000 to 70,000, and the weight average molecular weight is 5,000 to 500,000. In a case in which the average molecular weights are lower than these values, the mechanical strength needed when the resin composition is produced into a heat-conductive adhesive film is not readily manifested, and in a case in which the average molecular weights are higher than these values, the adhesiveness needed when the resin composition is produced into a heat-conductive adhesive film is not readily manifested.

The control of the molecular weight of the polyimide resin (A) can be implemented by adjusting the molar ratio R value between the sum of the diamine and the diaminodiphenol, and the tetracarboxylic acid dianhydride used in the reaction [=(diamine+diaminodiphenol)/(tetracarboxylic acid dianhydride). As the R value is closer to 1.00, the average molecular weight, increases. Thus, the R value is preferably 0.80 to 1.20, and more preferably, the R value is 0.9 to 1.1.

If the R value is less than 100, the polyimide resin (A) comes to have acid anhydride terminals, and if the R value is more than 1.00, the polyimide resin (A) comes to have amine terminals. It is not intended to limit the terminals of the present polyimide resin (A) to any one structure; however, it is preferable that the polyimide resin (A) has terminal amines.

It is preferable that the addition reaction and the dehydration-ring closure reaction are carried out in a solvent, that dissolves polyamic acid, which is an intermediate of the synthesis, and the present polyimide resin (A), for example, a solvent including one or more selected from N-methyl-2-pyrrolidone, N,N-dimethylacetamide, and γ-butyrolactone.

At the time of the dehydration-ring closure reaction, it is preferable to perform the reaction while removing the water produced as a side product of the reaction from the reaction system, by using a small amount of a non-polar solvent having a relatively low boiling point, such as toluene, xylene, hexane, cyclohexane or heptane, as a dehydrating agent. Furthermore, it is also preferable to add to the system a small amount of a basic organic compound selected from pyridine, N,N-dimethyl-4-aminopyridine and triethylamine as a catalyst. The reaction temperature used at the time of the addition reaction is usually 10° C. to 100° C., and preferably 40° C. to 90° C. The reaction temperature used at the time of the dehydration-ring closure reaction is usually 150° C. to 220° C., and preferably 160° C. to 200° C., and the reaction time is usually 2 hours to 15 hours, and preferably 5 hours to 10 The amount of addition of the dehydrating agent is usually 5% to 20% by mass with respect to the reaction liquid, and the amount of addition of the catalyst is usually 0.1% to 5% by mass with respect to the reaction liquid.

It is preferable that the polyimide resin (A) used for the present invention is soluble in a solvent, and after the dehydration-ring closure reaction, the polyimide resin is obtained as a varnish of the present, polyimide resin (A) dissolved in a solvent. The solvent is preferably, for example, N-methyl-2-pyrrolidone, N,N-dimethylacetamide, or γ-butyrolactone. Furthermore, it is preferable that the polyimide resin (A) also dissolves in any one or more of the solvents used for the varnish of the resin composition described below. According to an embodiment of the present invention, a method of adding a poor solvent such as water or an alcohol to a varnish of the present, polyimide resin (A), precipitating the polyimide resin (A), and using this precipitate after purification, may be used. Also, according to another embodiment, a varnish of the present polyimide resin (A) obtained after the dehydration-ring closure reaction may be used directly without purification, and from, the viewpoint of operability, this embodiment is more preferred.

The present resin composition may be obtained by incorporating additives such as a filler (B) and an epoxy resin (C) having a melt viscosity of 0.04 Pa·s or less into the polyimide resin (A) thus obtained.

Regarding the filler (B) used for the present invention, an inorganic filler, particularly a heat-conductive inorganic filler, is preferably used. An inorganic filler having a thermal conductivity of 1 W/m·k or more as measured by a laser flash method is preferred, and it is more preferable that the inorganic filler has a thermal conductivity of 5 W/m·k or more, and even more preferably 10 W/m·k or more. Specific examples of the filler (B) include, but are not limited to, aluminum hydroxide, magnesium hydroxide, calcium carbonate, magnesium carbonate, calcium silicate, calcium oxide, magnesium oxide, alumina, aluminum nitride, aluminum borate whiskers, silicon nitride, boron nitride, crystalline silica, amorphous silica, and silicon carbide. In order to increase the thermal conduction properties of the heat-conductive adhesive film, alumina, aluminum nitride, silicon nitride, boron nitride, crystalline silica, amorphous silica, and silicon carbide are preferred.

In regard to the present resin composition, it is even more preferable to use at least one selected from aluminum nitride and boron nitride as the filler (B), from the viewpoint of obtaining a high thermal conductivity.

In the case of boron nitride, scale-like microcrystals having an average particle size of the crystal grain of 2 μm or less, and scale-like microcrystals having a major axis of the crystal grain of 10 μm or less are known. In many cases, these microcrystals usually aggregate and thereby form relatively large secondary aggregated particles. According to the present invention, secondary aggregated particles having an average particle diameter of about 10 μm to 50 μm are preferred, and secondary aggregated particles having an average particle diameter of about 15 μm to 40 μm are more preferred. Therefore, when large secondary aggregated particles of boron nitride are used as a raw material, it is preferable to appropriately adjust the size of the secondary aggregated particles of boron nitride dispersed in the present, resin composition by appropriate pulverization or the like, so that the size of the secondary aggregated particles is in the range described above. The particle size of boron nitride may be adjusted in advance by stirring and mixing, or the like, or the adjustment of the secondary particles may be carried out simultaneously with mixing at the time of stirring and mixing or kneading with other raw materials.

In the case of aluminum nitride, since microcrystals having a size of about 0.6 μm are also similarly aggregated to form secondary aggregated microparticles having a size of about 1 μm to 2 μm, those secondary aggregated microparticles may be directly used.

The average particle size may be measured by sampling the liquid during stirring and mixing. Measurement of the average particle size may be performed using a grind gauge (particle size gauge) or a laser diffraction particle size distribution analyzer.

Since the present resin composition includes an epoxy resin, when the resin composition is produced into a heat-conductive adhesive film, the glass transition temperature of the cured layer obtained after adhesive lamination may be adjusted to 200° C. or higher. Furthermore, when the epoxy resin is selected to an epoxy resin (C) having a melt viscosity of 0.04 Pa·s or less, the specifically satisfactory electrical insulation properties, thermal conductivity, and satisfactory adhesiveness at a low temperature, which are the effects of the present invention, may be manifested.

Meanwhile, according to the present invention, for the melt viscosity of the epoxy resin, a melt, viscosity measured using a cone-plate type viscometer at 150° C. is employed.

Specific examples of the epoxy resin (C) having a melt viscosity of 0.04 Pa·s or less that is incorporated into the present resin composition include, but are not limited to, bisphenol A type epoxy resins (for example, JER828 (manufactured by Mitsubishi Chemical Corp.), EP4100 (manufactured by Adeka Corp.), 850-S (manufactured by DIC Corp.), RE-310S (manufactured by Nippon Kayaku Co., Ltd.), and RIKARESIN BEG-60E (manufactured by New Japan Chemical Co., Ltd.)), bisphenol F type epoxy resins (for example, YDF-870GS (manufactured by Nippon Steel & Sumikin Chemical Co., Ltd.), and RE-303S (manufactured by Nippon Kayaku Co., Ltd.)), and biphenol skeleton epoxy resins or alkylbiphenol skeleton epoxy resins (for example, YX-4000 (manufactured by Mitsubishi Chemical Corp.) and YL6121H (manufactured by Mitsubishi Chemical Corp.)). Two or more kinds of these epoxy resins may be used in combination. These epoxy resins include resins that are solid at normal temperature, and resins that are liquid at normal temperature, and both can be used.

Regarding the present resin composition, the ratio of the amounts in parts by mass of the polyimide resin (A) and the epoxy resin (C) is such that (A):(C)=99:1 to 1:99, and preferably 95:5 to 5:99, and in the case of a resin composition for a heat-conductive adhesive film of a silicon carbide-based power module, it is preferable to incorporate the resins so that the ratio is (A):(C)=90:10 to 10:90. Furthermore, it is preferable that the ratio of the amounts in parts by mass of the polyimide resin (A), the filler (B), and the epoxy resin (C) satisfies the relationship: ((A)+(C)):(B)=80:20 to 5:95. When the mass ratio of the components (A), (B) and (C) satisfies the above-described relationship, the electrical insulation properties, thermal conductivity, adhesiveness at a low temperature, and glass transition temperature needed by a heat-conductive adhesive film for a silicon carbide-based power module may be satisfied. The mass ratio is more preferably such that (A):(C)=80:20 to 20:80, and even more preferably (A):(C)=70:30 to 30:70. Furthermore, it is more preferable that the relationship: ((A)+(C)):(B)=50:50 to 10:90 is satisfied, and it is even more preferable that the relationship: ((A)+(C)):(B)=40:60 to 20:80 is satisfied.

An epoxy resin having a melt viscosity of more than 0.04 Pa·s may be incorporated for the adjustment of the physical properties of the heat-conductive adhesion film, to the extent, that the effects of the present, invention are not impaired. Specific examples of such an epoxy resin, include, but are not limited to, novolac type epoxy resins (for example, N-660 (manufactured, by DIG Corp.), YDCN-700-5 (manufactured by Nippon. Steel & Sumikin Chemical Co., Ltd.), EOCN-1020 (manufactured by Nippon Kayaku Co., Ltd.), and EPPN-501H (manufactured, by Nippon Kayaku Co., Ltd.)), dicyclopentadiene-phenol condensed type epoxy resins (for example, XD-1000 (manufactured by Nippon Kayaku. Co., Ltd.)), xylene skeleton-containing phenol-novolac type epoxy resins (for example, NC-2000 (manufactured by Nippon Kayaku Co., Ltd.)), biphenyl skeleton-containing novolac type epoxy resins (for example, NC-3000 (manufactured by Nippon Kayaku Co., Ltd.)), naphthalene type epoxy resins (for example, HP-4710 (manufactured by DIC Corp.)), and alicyclic epoxy resins (for example, CELLOXIDE 2021P (manufactured by Daicel Corp.)). Two or more kinds of these epoxy resins may be used in combination. As a reference for the amount of use of the epoxy resin having a melt viscosity of more than 0.04 Pa·s, when the sum of the masses of the polyimide resin (A) and the epoxy resin (C) having a melt viscosity of 0.04 Pa·s or less is designated as 100 parts, the amount of use of the epoxy resin is preferably 50 parts or less, more preferably 40 parts or less, and even more preferably 20 parts or less.

In the present resin composition, additives for manifesting various physical properties may be incorporated in addition to the components described above. For example, it is one preferred embodiment of the present invention to incorporate an epoxy resin curing agent and a curing accelerating agent.

Specific examples of the epoxy resin curing agent include, but are not limited to, diaminodiphenylmethane, diethylenetriamine, triethylenetetramine, diaminodiphenylsulfone, isophoronediamine, dicyandiamide, a polyamide resin synthesized from a dimer of linolenic acid and ethylenediamine, phthalic anhydride, trimellitic anhydride, pyromellitic anhydride, maleic anhydride, tetrahydrophthalic anhydride, methyltetrahydrophthalic anhydride, methyl nadic anhydride, hexahydrophthalic anhydride, methylhexahydrophthalic anhydride, a polyhydric phenol compound such as phenol novolac, triphenylmethane and modification products thereof, imidazole, a BF₃-amine complex, and a guanidine derivative. The epoxy resin curing agent may be selected depending on the embodiment of use.

For example, according to one preferred embodiment of the present invention, a polyhydric phenol compound is used, and preferably, a phenol novolac obtainable by subjecting phenol, formaldehyde, and benzene, biphenyl or the like to a condensation reaction is preferred.

In a case in which an epoxy resin curing agent is incorporated, the content, of the curing agent, may also vary depending on the curing agents that, are used in combination therewith, and it cannot be said as a rule; however, the content of the curing agent is preferably 500 parts by mass or less, and more preferably 100 parts by mass or less, relative to 100 parts by mass of the total amount of the epoxy resin. If the content is larger than this, the heat resistance of the heat-conductive adhesive film may be deteriorated. Meanwhile, in regard to the present resin composition, at the time of the curing reaction, first, the phenolic hydroxyl groups in the polyimide (A) and the hydroxyl groups or amino groups in the curing agent, as an optional component stoichiometrically react with all of the epoxy groups of the epoxy resins included in the composition. In a case in which the epoxy groups of the epoxy resins are present in excess with respect to the sum of the phenolic hydroxyl groups in the polyimide (A) and the hydroxyl groups or amino groups in the curing agent as an optional component, the secondary hydroxyl groups generated by a ring opening reaction of the epoxy groups react with residual epoxy groups, and thereby the reaction is completed. Thus, there is no problem. On the other hand, if the phenolic hydroxyl groups and the like are present in excess with respect to the epoxy groups, unreacted phenolic hydroxyl groups and the like remain in the cured product, and electrical insulation properties may be deteriorated, which is not preferable. In regard to the present resin composition, it is preferable that the mole number of the epoxy groups is 1.0 times or more, more preferably 1.05 times or more, and even more preferably 1.2 or more, of the sum of the mole numbers of the phenolic hydroxyl groups and the hydroxyl groups or amino groups in the curing agent as an optional component. The mole number of the phenolic hydroxyl groups in the polyimide (A), the mole number of the hydroxyl groups or amino groups in the curing agent as an optional component, and the mole number of the epoxy groups in the epoxy resin may be each calculated by dividing the amount, in parts by mass of each of the groups by the functional group equivalent.

Furthermore, specific examples of the curing accelerating agent that may be used for the present invention include, but are not limited to, imidazoles such as 2-methylimidazole, 2-ethylimidazole, 2-ethyl-4-methyl imidazole, 2-phenyl-4, 5-dihydroxymethyl imidazole, 2-phenyl-4-methyl-5-hydroxymethylimidazole, and 2-phenylimidazole; triazines such as 2,4-diamino-6-[2′-undecylimidazolyl-(1′)]-ethyl-s-triazine, and 2,4-diamino-6-[2′-methylimidazolyl-(1′)]-ethyl-s-triazine; tertiary amines such as 2-(dimethylaminomethyl)phenol, and 1,8-diazabicyclo(5,4,0)-undecene-7; phosphines such as triphenylphosphine; and metal compounds such as tin octoate. The curing accelerating agent is used as necessary, in an amount of 0.1 parts to 5.0 parts by mass relative to 100 parts by mass of the epoxy resin.

In the present resin composition, additives, for example, a coupling agent, an organic solvent, and an ion scavenger, may be added if necessary. The coupling agent used therein is not particularly limited; however, a silane coupling agent is preferred, and specific examples thereof include γ-glycidoxypropyltrimethoxysilane, γ-mercaptopropyltrimethoxysilane, γ-aminopropyltriethoxysilane, γ-ureidopropyltriethoxysilane, and N-β-aminoethyl-γ-aminopropyltrimethoxysilane. The amount of use of these coupling agents may be selected depending on the use of the resin composition, the kind of the coupling agent, or the like, and the amount of use is usually 5 parts by mass or less relative to 100 parts by mass of the present resin composition.

The ion scavenger that may be used in the present resin composition is not particularly limited; however, examples thereof include a triazinethiol compound that is known as a copper inhibitor for preventing copper from ionizing and dissolving out; a bisphenol-based reducing agent, such, as 2,2′-methylene bis(4-methyl-6-tertiary-butylphenol); and an inorganic ion adsorbent such as a zirconium-based, compound, an antimony-bismuth-based compound, a magnesium-aluminum-based compound, and hydrotalcite. By adding these ion scavengers, ionic impurities are adsorbed thereto, and the electrical reliability at the time of moisture absorption, may be enhanced. The amount of use of the ion scavenger is usually 5% by mass or less in the present resin composition, from the viewpoints of the effects and the balance between heat resistance, cost and the like.

The present resin composition may be used as a varnish dissolved in an organic solvent. Examples of the organic solvent that may be used include lactones such as γ-butyrolactone; amide-based, solvents such as N-methylpyrrolidone (NMP), N,N-dimethylformamide (DMF), N,N-dimethylacetamide, and N,N-dimethylimidazolidinone; sulfones such as tetramethylenesulfone; ether-based solvents such as dlethylene glycol dimethyl ether, diethylene glycol diethyl ether, propylene glycol, propylene glycol monomethyl ether, propylene glycol monomethyl ether monoacetate, and propylene glycol monobutyl ether; ketone-based solvents such as acetone, methyl ethyl ketone, methyl isobutyl ketone, cyclopentanone, and cyclohexanone; and aromatic solvents such as toluene and xylene. A mixture of two or more kinds of organic solvents may also be used. In order to regulate the drying speed in a coating and drying process, a mixed solvent of a high boiling point solvent and a low boiling point solvent, for example, γ-butyrolactone (boiling point: 204° C.) and methyl ethyl ketone (boiling point: 79.6° C.), is preferably used in the present invention. The amount, of use of these organic solvents is usually 90% by mass or less, preferably 70% by mass or less, and more preferably 50% by mass or less, in the present varnish.

The present varnish is used to produce the present heat-conductive adhesive film through a coating and drying process, and is also preferably used in other applications where thermal conduction properties are required. Specific examples include, for example, an application in which a coil used in a power unit such as a motor is impregnated with the varnish and dried, and thereby the varnish is used as a heat-conductive heat-resistant coating material; and an application in which the varnish is used as an electroconductive bonding material between a circuit wiring and an electronic component in a process for mounting an electronic component (application as a substitute for solder bonding). In order to use the varnish as an electroconductive bonding material, it is preferable that in addition to a heat-conductive filler, electroconductive particles such as a silver powder or a copper powder are incorporated in to the resin composition.

In a case in which the dispersion of the heat-conductive filler is considered, the varnish may be produced by means of a Raikai mixer, a three-roll, a bead mill or the like, or by means of a combination thereof. Also, by mixing the heat-conductive filler and low molecular weight components in advance, and then incorporating high molecular weight components, the time required for mixing can be shortened. Furthermore, it is preferable to remove air bubbles included in the varnish thus obtained when the various components are mixed, from the varnish through vacuum degassing.

The present resin composition may be produced into the present heat-conductive adhesive film by applying the varnish on a substrate, and then drying the organic solvent, to form a film. Regarding the substrate used on the occasion of film formation, a polyethylene terephthalate film, a polyethylene film, a polypropylene film, a polyester film, a fluorine film, a copper foil, a stainless steel form, and the like are suitable. In a case in which the substrate is detached after drying to obtain a single film, the surfaces of these substrates may be subjected to a release treatment with silicone or the like. Specifically, a film formed from the present resin composition may be obtained by applying a varnish of the present resin composition on the surface of a substrate using a comma coater, a die coater, a gravure coater or the like, volatilizing the solvent in the coating material using hot air, an infrared heater or the like to the extent that a curing reaction does not proceed, and then detaching the resultant from the substrate. Furthermore, in a case in which the substrate used here is directly used as an adherend for the present resin composition, it is acceptable not to detach the substrate after the solvent is volatilized.

The thickness of the present heat-conductive adhesive film is usually 2 μm to 500 μm, and preferably 5 μm to 300 μm. If the thickness of the film is too thin, the adhesive strength toward the adherend is markedly decreased, and if the thickness of the film is too thick, the amount of solvent remaining in the film becomes large, so that when the adhesion product to the adherend is subjected to an environmental test, defects such as lifts or blisters are generated.

There are no particular limitations on the use of the present heat-conductive adhesive film; however, since the heat-conductive adhesive film has effects such as heat resistance, high thermal conduction properties (heat dissipation properties), adhesiveness and electrical insulation properties, the heat-conductive adhesive film is preferably used to adhere an electrical circuit, a metal foil or a circuit board to a heat dissipation plate. The material of the metal foil is not particularly limited; however, from the viewpoint of general-purpose usability, a copper foil, an aluminum foil or a stainless steel foil is preferred.

Furthermore, the present heat-conductive adhesive film is also preferably used to adhere, for example, a power module of a silicon carbide-based power module or the like to a cooler. A power module is a device in which plural power elements (power MOSFETs, IGBTs, or the like) are wire connected to a ceramic substrate or the like and are incorporated into one package. A typical example is a configuration in which a power element is provided on the front, side, and heat is mainly dissipated through the back, surface; however, there is also a configuration of a type in which heat, can be dissipated through two surfaces, as a result of devising the configuration. The cooler may be any cooler capable of cooling a power module by heat exchange, and may be of a water cooling type or an air cooling type.

According to one preferred application of the present heat-conductive adhesive film, a cooler may be directly adhered to either surface of a power module of a type in which heat can be dissipated through both surfaces, by interposing a cured layer of the present heat-conductive adhesive film between the surface of the power module and the cooler.

The heat dissipation plate as used herein is a plate laminated on a surface where an electronic component is mounted for the purpose of accelerating heat dissipation from an electronic component mounted on an electrical circuit, and usually, a metal plate or the like is used. Examples of the material for the heat dissipation plate include metals such as copper, aluminum, stainless steel, nickel, iron, gold, silver, molybdenum and tungsten; composites of metals and glass; and alloys. Among them, copper, aluminum, gold, silver or iron, all of which have high thermal conductivities, and an alloy using these is preferred. The thickness of the heat dissipation plate is not particularly limited; however, in view of processability, the thickness is usually 0.1 mm to 5 mm. When the present resin composition is applied as a varnish on this heat dissipation plate or a metal foil, and this varnish is dried, or when the single adhesive film described above is laminated thereon, a heat dissipation plate attached with a heat-conductive adhesive film formed from the present resin composition, and a metal foil attached with a heat-conductive adhesive film formed from, the present resin composition are obtained.

A laminate including a metal foil, a cured layer of the present resin composition and a heat dissipation plate is obtained by stacking a heat dissipation plate attached with a heat-conductive adhesive film formed from the present resin composition with a metal foil, or a metal foil attached with a heat-conductive adhesive film formed from the present resin composition with a heat dissipation plate, or a heat dissipation plate with the present heat-conductive adhesive film alone and a metal foil, and hot pressing the assembly using a hot plate pressing machine, a hot roll pressing machine or the like. Furthermore, the present electronic component may be obtained by stacking, for example, a power module, the present heat-conductive adhesive film and a cooler, and hot pressing the assembly using a hot plate pressing machine, a hot roll pressing machine or the like; however, the present electronic component is not intended to be limited to the configurations described above. The hot pressing temperature is preferably 170° C. to 200° C., at which a hot roll pressing machine having high production efficiency can be used, and the pressing pressure is preferably 0.5 MPa to 15 MPa.

A laminate in which an electrical circuit, a cured layer of the present resin composition, and a heat dissipation plate are laminated may be produced by processing a laminate including a metal foil, a cured layer of the present resin composition and a heat dissipation plate to form a circuit in the metal foil part. Also, mounting of an electronic component on the electrical circuit is carried out by solder connection or the like, and thus an electronic component having a cured layer of the present resin composition is obtained.

### EXAMPLES

Next, the present invention will be more specifically explained by way of Examples and Comparative Examples; however, the present invention is not intended to be limited to these Examples. Meanwhile, the unit “parts” in the Examples means parts by mass, and the unit “percent (%)” means percent (%) by mass. Incidentally, m and n in Formula (1) may be calculated using the following formulas (a) and (b). In the following formulas (a) and (b), R represents the molar ratio R value between the sum of a diamine that does not have a phenolic hydroxyl group and a diaminodiphenol, which are used in the reaction, and a tetracarboxylic acid dianhydride [=(diamine not having a phenolic hydroxyl group+diaminodiphenol)/tetracarboxylic acid dianhydride]. Furthermore, M and N the mole numbers of the diamine not having a phenolic hydroxyl group and the diaminodiphenol, respectively, which are used in the reaction.

m+n=100/(100R−100) (a)

n/(m+n)=N/(M+N) (b)

### Synthesis Example 1

Into a 500-ml reactor equipped with a thermometer, a reflux cooler, a Dean-Stark apparatus, a powder inlet port, a nitrogen introducing apparatus and a stirring apparatus, 30.79 parts (0.105 moles) of APB-N (1,3-bis(3-aminophenoxy)benzene, manufactured by Mitsui Chemicals, Inc., molecular weight: 292.33) as a diamine compound, and 0.467 parts (0.0017 moles) of ABPS (3,3′-diamino-4,4′-dihydroxydiphenylsulfone, manufactured by Nippon Kayaku. Co., Ltd., molecular weight: 280.30) as a diaminophenol compound were introduced, and while dry nitrogen was blown, 68.58 of γ-butyrolactone was added thereto as a solvent. The mixture was stirred for 30 minutes at 70° C. Thereafter, 32.54 parts (0.105 moles) of ODPA (4,4′-oxydiphthalic anhydride, manufactured by Manac, Inc., molecular weight: 310.22) as a tetracarboxylic acid, dianhydride, 71.40 parts of γ-butyrolactone as a solvent, 1.66 parts of pyridine as a catalyst, and 28.49 parts of toluene as a dehydrating agent, were added thereto, and the temperature inside the reactor was increased to 180° C. While the water generated by an imidization reaction was removed using the Dean-Stark apparatus, a heated ring-closure reaction was carried out for 3 hours at 180° C., and then heating was performed for another 4 hours to remove pyridine and toluene. After completion of the reaction, the reaction liquid was cooled to a temperature of 80° C. or lower, and the reaction liquid was subjected to pressurized filtration using a filter made of TEFLON (registered trademark) and having a pore size of 3 μm. Thus, 200 parts of the present polyimide resin varnish containing 30% of the present polyimide resin (A) represented by the following Formula (8):

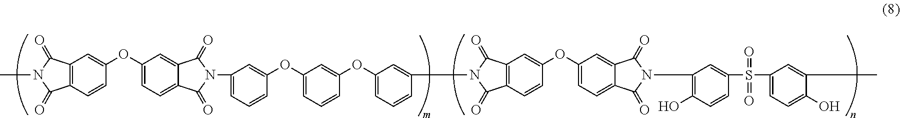

was obtained. The number average molecular weight determined based on the analysis results that were obtained by gel permeation chromatography of the present polyimide resin (A) in the polyimide resin varnish and calculated relative to polystyrene standards, was 36,000, and the weight average molecular weight thus determined was 97,000, The value of m in Formula (8) as calculated from the molar ratio of the various components used in the synthesis reaction was 49.22, while the value of n was 0.78. The R value was 1.02.

### Synthesis Example 2

Into a 500-ml reactor equipped with a thermometer, a reflux cooler, a Dean-Stark apparatus, a powder inlet port, a nitrogen introducing apparatus and a stirring apparatus, 30.63 parts (0.105 moles) of APB-N (1,3-bis(3-aminophenoxy)benzene, manufactured by Mitsui Chemicals, Inc., molecular weight: 292.33) as a diamine compound, and 0.623 parts (0.0022 moles) of ABPS (3,3′-diamino-4,4′-dihydroxydiphenylsulfone, manufactured by Nippon Kayaku Co., Ltd., molecular weight: 280.30) as a diaminophenol compound were introduced, and while dry nitrogen was blown, 68.58 of γ-butyrolactone was added thereto as a solvent. The mixture was stirred for 30 minutes at 70° C. Thereafter, 32.54 parts (0.105 moles) of ODPA (4,4′-oxydiphthalic anhydride, manufactured by Manac, Inc., molecular weight: 310.22) as a tetracarboxylic acid dianhydride, 71.41 parts of γ-butyrolactone as a solvent, 1.66 parts of pyridine as a catalyst, and 28.49 parts of toluene as a dehydrating agent were added thereto, and the temperature inside the reactor was increased to 180° C. While the water generated by an imidization reaction was removed using the Dean-Stark apparatus, a heated ring-closure reaction was carried out for 3 hours at 180° C., and then heating was performed for another 4 hours to remove pyridine and toluene. After-completion of the reaction, the reaction liquid was cooled to a temperature of 80° C. or lower, and the reaction liquid was subjected to pressurized filtration using a filter made of TEFLON (registered trademark) and having a pore size of 3 μm. Thus, 200 parts of the present polyimide resin varnish containing 30% of the present polyimide resin (A) represented by the following Formula (8):

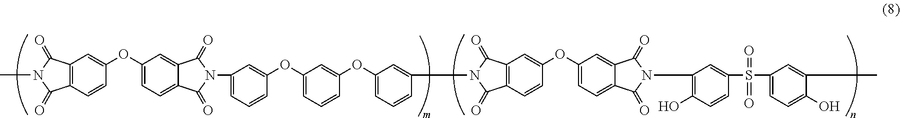

was obtained. The number average molecular weight determined based on the analysis results that were obtained by gel permeation chromatography of the present polyimide resin (A) in the polyimide resin varnish and calculated relative to polystyrene standards, was 38,000, and the weight average molecular weight thus determined was 102,000, The value of m in Formula (8) as calculated from the molar-ratio of the various components used in the synthesis reaction was 48.96, while the value of n was 1.04. The R value was 1.02.

### Synthesis Example 3

Into a 500-ml reactor equipped with a thermometer, a reflux cooler, a Dean-Stark apparatus, a powder inlet port, a nitrogen introducing apparatus and a stirring apparatus, 30.31 parts (0.104 moles) of APB-N (1,3-bis(3-aminophenoxy)benzene, manufactured by Mitsui Chemicals, Inc., molecular weight: 292.33) as a diamine compound, and 0.935 parts (0.0033 moles) of ABPS (3,3′-diamino-4,4′-dihydroxydiphenylsulfone, manufactured by Nippon Kayaku Co., Ltd., molecular weight: 280.30) as a diaminophenol compound were introduced, and while dry nitrogen was blown, 68.56 of γ-butyrolactone was added thereto as a solvent. The mixture was stirred for 30 minutes at 70° C. Thereafter, 32.55 parts (0.105 moles) of ODPA (4,4′-oxydiphthalic anhydride, manufactured by Manac, Inc., molecular weight: 310.22) as a tetracarboxylic acid dianhydride, 71.42 parts of γ-butyrolactone as a solvent, 1.66 parts of pyridine as a catalyst, and 28.49 parts of toluene as a dehydrating agent were added thereto, and the temperature inside the reactor was increased to 180° C. While the water generated by an imidization reaction was removed using the Dean-Stark apparatus, a heated ring-closure reaction was carried out for 3 hours at 180° C., and then heating was performed for another 4 hours to remove pyridine and toluene. After completion of the reaction, the reaction liquid was cooled to a temperature of 80° C. or lower, and the reaction liquid was subjected to pressurized filtration using a filter made of TEFLON (registered trademark) and having a pore size of 3 μm. Thus, 200 parts of the present polyimide resin varnish containing 30% of the present polyimide resin (A) represented by the following Formula (8):

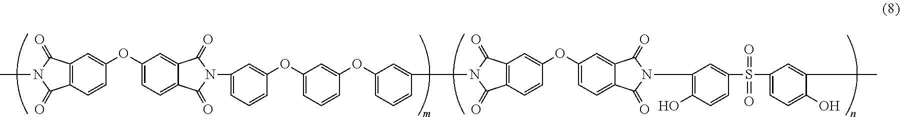

was obtained. The number average molecular weight determined based on the analysis results that were obtained by gel permeation chromatography of the present polyimide resin (A) in the polyimide resin varnish and calculated relative to polystyrene standards, was 41,000, and the weight average molecular weight thus determined was 109,000. The value of m in Formula (8) as calculated from the molar ratio of the various components used in the synthesis reaction was 48.44, while the value of n was 1.56. The R value was 1.02.

### Synthesis Example 4

### Synthesis of Polyimide Resin with n/m+n=0.04, as Described in JP 2011-225675 A)

Into a 500-ml reactor equipped with a thermometer, a reflux cooler, a Dean-Stark apparatus, a powder inlet port, a nitrogen introducing apparatus and a stirring apparatus, 30.04 parts (0.103 moles) of APB-N (1,3-bis(3-aminophenoxy)benzene, manufactured by Mitsui Chemicals, Inc., molecular weight: 292.33) as a diamine compound, and 1.200 parts (0.0043 moles) of ABPS (3,3′-diamino-4,4′-dihydroxydiphenylsulfone, manufactured by Nippon Kayaku Co., Ltd., molecular weight: 280.30) as a diaminophenol compound were introduced, and while dry nitrogen was blown, 68.55 of γ-butyrolactone was added thereto as a solvent. The mixture was stirred for 30 minutes at 70° C. Thereafter, 32.56 parts (0.105 moles) of ODPA (4,4′-oxydiphthalic anhydride, manufactured by Manac, Inc., molecular weight: 310.22) as a tetracarboxylic acid dianhydride, 71.43 parts of γ-butyrolactone as a solvent, 1.66 parts of pyridine as a catalyst, and 28.49 parts of toluene as a dehydrating agent were added thereto, and the temperature inside the reactor was increased to 180° C. While the water generated by an imidization reaction was removed using the Dean-Stark apparatus, a heated ring-closure reaction was carried out for 3 hours at 180° C., and then heating was performed for another 4 hours to remove pyridine and toluene. After completion of the reaction, the reaction liquid was cooled to a temperature of 80° C. or lower, and the reaction liquid was subjected to pressurized filtration using a filter made of TEFLON (registered trademark) and having a pore size of 3 μm. Thus, 200 parts of the present polyimide resin varnish containing 30% of the present polyimide resin (A) represented by the following Formula (8):

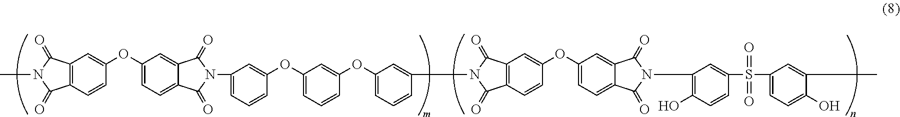

was obtained. The number average molecular weight determined based on the analysis results that were obtained by gel permeation chromatography of the present polyimide resin (A) in the polyimide resin varnish and calculated relative to polystyrene standards, was 42,000, and the weight average molecular weight thus determined was 110,000, The value of m in Formula (8) as calculated from the molar-ratio of the various components used in the synthesis reaction was 48.00, while the value of n was 2.00. The R value was 1.02.

### Synthesis Example 5

Into a 500-ml reactor equipped with a thermometer, a reflux cooler, a Dean-Stark apparatus, a powder inlet, port, a nitrogen introducing apparatus and a stirring apparatus, 30.54 parts (0.104 moles) of APB-N (1,3-bis(3-aminophenoxy)benzene, manufactured by Mitsui Chemicals, Inc., molecular weight: 292.33) as a diamine compound, and 0.814 parts (0.0022 moles) of BAFA (2,2-bis(3-amino-4-hydroxyphenyl)hexafluoropropane, manufactured by Nippon Kayaku Co., Ltd., molecular weight: 366.26) as a diaminophenol compound were introduced, and while dry nitrogen, was blown, 68.79 parts of γ-butyrolactone was added thereto as a solvent. The mixture was stirred for 30 at 70° C. Thereafter, 32.44 parts (0.105 moles) of ODPA (4,41-oxydiphthalic anhydride, manufactured by Manac, Inc., molecular weight: 310.22) as a tetracarboxylic acid, dianhydride, 71.19 parts of γ-butyrolactone as a solvent, 1.66 parts of pyridine as a catalyst, and 28.49 parts of toluene as a dehydrating agent were added thereto, and the temperature inside the reactor was increased to 180° C. While the water generated by an imidization reaction was removed using the Dean-Stark, apparatus, a heated ring-closure reaction was carried out for 3 hours at 180° C., and then heating was performed for another 4 hours to remove pyridine and toluene. After completion of the reaction, the reaction liquid was cooled to a temperature of 80° C. or lower, and the reaction liquid was subjected to pressurized filtration using a filter made of TEFLON (registered trademark) and having a pore size of 3 μm. Thus, 200 parts of the present polyimide resin varnish containing 30% of the present, polyimide resin (A) represented by the following Formula (9):

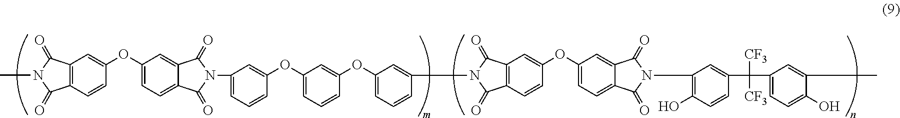

was obtained. The number average molecular weight determined based on the analysis results that were obtained by gel permeation chromatography of the present polyimide resin (A) in the polyimide resin varnish and calculated relative to polystyrene standards, was 40,000, and the weight average molecular weight thus determined was 100,000, The value of m in Formula (9) as calculated from the molar-ratio of the various components used in the synthesis reaction was 48.96, while the value of n was 1.04. The R value was 1.02.

Into a 500-ml reactor equipped with a thermometer, a reflux cooler, a Dean-Stark apparatus, a powder inlet port, a nitrogen introducing apparatus and a stirring apparatus, 30.70 parts (0.105 moles) of APB-N (1,3-bis(3-aminophenoxy)benzene, manufactured by Mitsui Chemicals, Inc., molecular weight: 292.33) as a diamine compound, and 0.481 parts (0.0022 moles) of HAB (3,3′-diaminobiphenyl-4,4′-diol, manufactured by Nippon Kayaku Co., Ltd., molecular weight: 216.24) as a diaminophenol compound were introduced, and while dry nitrogen was blown, 68.42 parts of γ-butyrolactone was added thereto as a solvent. The mixture was stirred for 30 minutes at 70° C. Thereafter, 32.62 parts (0.105 moles) of ODPA (4,4′-oxydiphthalic anhydride, manufactured by Manac, Inc., molecular weight: 310.22) as a tetracarboxylic acid, dianhydride, 71.57 parts of γ-butyrolactone as a solvent, 1.66 parts of pyridine as a catalyst, and 28.49 parts of toluene as a dehydrating agent, were added thereto, and the temperature inside the reactor was increased to 180° C. While the water generated by an imidization reaction was removed using the Dean-Stark apparatus, a heated ring-closure reaction was carried out for 3 hours at 180° C., and then heating was performed for another 4 hours to remove pyridine and toluene. After completion of the reaction, the reaction liquid, was cooled to a temperature of 80° C. or lower, and the reaction liquid was subjected to pressurized filtration using a filter made of TEFLON (registered trademark) and having a pore size of 3 μm. Thus, 200 parts of the present polyimide resin varnish containing 30% of the present polyimide resin (A) represented by the following Formula (10):

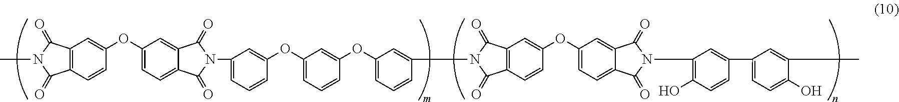

was obtained. The number average molecular weight determined based on the analysis results that, were obtained, by gel permeation chromatography of the present, polyimide resin (A) in the polyimide resin varnish and calculated, relative to polystyrene standards, was 37,000, and the weight average molecular weight thus determined was 99,000. The value of m in Formula (10) as calculated from, the molar ratio of the various components used in the synthesis reaction, was 48.96, while the value of n was 1.04. The R value was 1.02.

### Synthesis Example 7

### Synthesis of Comparative Polyimide Resin in which n=0)

Into a 500-ml reactor equipped with a thermometer, a reflux cooler, a Dean-Stark apparatus, a powder inlet port, a nitrogen introducing apparatus and a stirring apparatus, 31.27 parts (0.107 moles) of APB-N (1,3-bis(3-aminophenoxy)benzene, manufactured by Mitsui Chemicals, Inc., molecular weight: 292.33) as a diamine compound was introduced, and while dry nitrogen was blown, 68.61 parts of γ-butyrolactone was added thereto as a solvent. The mixture was stirred for 30 minutes at 70° C. Thereafter, 32.53 parts (0.105 moles) of ODPA (4,4′-oxydiphthalic anhydride, manufactured by Manac, Inc., molecular weight: 310.22) as a tetracarboxylic acid dianhydride, 71.37 parts of γ-butyrolactone as a solvent, 1.66 parts of pyridine as a catalyst, and 28.49 parts of toluene as a dehydrating agent were added thereto, and the temperature inside the reactor was increased to 180° C. While the water generated by an imidization reaction was removed using the Dean-Stark apparatus, a heated ring-closure reaction was carried out for 3 hours at 180° C., and then heating was performed for another 4 hours to remove pyridine and toluene. After-completion of the reaction, the reaction liquid was cooled to a temperature of 80° C. or lower, and the reaction liquid was subjected to pressurized filtration using a filter made of TEFLON (registered trademark) and having a pore size of 3 μm. Thus, 200 parts of the present polyimide resin varnish containing 30% of the present, polyimide resin (A) represented by the following Formula (11):

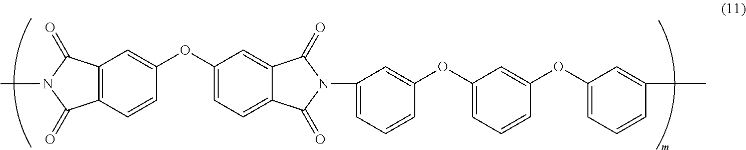

was obtained. The number average molecular weight determined based on the analysis results that were obtained by gel permeation chromatography of the present polyimide resin (A) in the polyimide resin varnish and calculated relative to polystyrene standards, was 22,000, and the weight average molecular weight thus determined was 77,000, The value of m in Formula (11) as calculated from the molar ratio of the various components used in the synthesis reaction was 50.00, while the value of n was 0. The R value was 1.02.

### Synthesis Example 8

### Synthesis of Comparative Polyimide Resin in which n/m+n=0.17

Into a 500-ml reactor equipped with a thermometer, a reflux cooler, a Dean-Stark apparatus, a powder inlet, port, a nitrogen introducing apparatus and a stirring apparatus, 26.06 parts (0.089 moles) of APB-N (1,3-bis(3-aminophenoxy)benzene, manufactured by Mitsui Chemicals, Inc., molecular weight: 292.33) as a diamine compound and 5.097 parts (0.0182 moles) of ABPS (3,3′-diamino-4,4′-dihydroxydiphenylsulfone, manufactured by Nippon Kayaku. Co., Ltd., molecular weight: 280.30) as a diaminophenol compound were introduced, and while dry nitrogen was blown, 68.37 of γ-butyrolactone was added thereto as a solvent. The mixture was stirred for 30 minutes at 70° C. Thereafter, 32.64 parts (0.105 moles) of ODPA (4,4′-oxydiphthalic anhydride, manufactured by Manac, Inc., molecular weight: 310.22) as a tetracarboxylic acid dianhydride, 71.62 parts of γ-butyrolactone as a solvent, 1.67 parts of pyridine as a catalyst, and 28.49 parts of toluene as a dehydrating agent were added thereto, and the temperature inside the reactor was increased to 180° C. While the water generated by an imidization reaction was removed using the Dean-Stark apparatus, a heated ring-closure reaction was carried out for 3 hours at 180° C., and then heating was performed for another 4 hours to remove pyridine and toluene. After completion of the reaction, the reaction liquid was cooled to a temperature of 80° C. or lower, and the reaction liquid was subjected to pressurized filtration using a filter made of TEFLON (registered trademark) and having a pore size of 3 μm. Thus, 200 parts of the present polyimide resin varnish containing 30% of the present polyimide resin (A) represented by the following Formula (8):

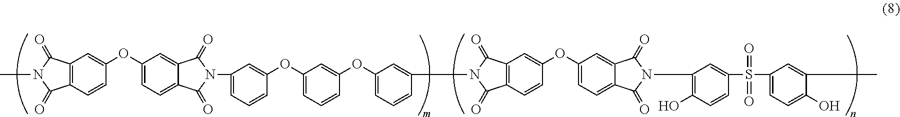

was obtained. The number average molecular weight determined based on the analysis results that were obtained by gel permeation chromatography of the present polyimide resin (A) in the polyimide resin varnish and calculated relative to polystyrene standards, was 44,000, and the weight average molecular weight thus determined was 117,000. The value of m in Formula (8) as calculated from the molar ratio of the various components used in the synthesis reaction was 41.53, while the value of n was 8.47. The R value was 1.02.

### Synthesis Example 9

### Synthesis of Comparative Phenolic Hydroxyl Group-Containing Aromatic Polyamide Resin

While a flask equipped with a thermometer, a cooling tube, a fractionating column and a stirrer was purged with nitrogen, 3.64 parts (0.02 moles) of 5-hydroxyisophthalic acid, 162.81 parts (0.98 moles) of isophthalic acid, 204.24 (102 moles) of 3,4′-diaminodiphenyl ether, 10.68 parts of lithium chloride, 1105 parts of N-methylpyrrolidone, and 236.28 parts of pyridine were introduced into the flask. After the mixture was stirred and dissolved, 512.07 parts of triphenyl phosphite was added thereto, and the reaction mixture was subjected to a condensation reaction for 4 hours at 95° C. Thus, a reaction liquid containing a phenolic hydroxyl group-containing aromatic polyamide resin was obtained. While this reaction liquid was stirred, 670 parts of water at 90° C. was added dropwise thereto over 3 hours, and the mixture was stirred for another one hour at 90° C. Thereafter, the reaction mixture was cooled to 60° C. and was left to stand for 30 minutes. Because the reaction mixture was separated such that, the upper layer was an aqueous layer, while the lower layer was an oil layer (resin layer), the upper layer was removed by decantation. The amount of the upper layer thus removed was 1200 parts. 530 parts of N, N-dimethylformamide was added to the oil layer (resin layer), and thereby a dilution, liquid of the oil layer was obtained. 670 parts of water was added to the dilution, liquid, and the mixture was left to stand still. After the layer separation, the aqueous layer was removed by decantation. This water washing process was repeated four times, and thus washing of the phenolic hydroxyl group-containing aromatic polyamide resin was carried out. After completion of the water washing, the dilution liquid of the component (A″) thus obtained was sprayed into 8000 parts of stirred water using two fluid nozzles, and a fine powder of the component (A″) having a particle size of 5 μm to 50 μm thus precipitated was separated by filtration. A wet cake of the precipitate thus obtained was dispersed in 2700 of methanol, and the dispersion was refluxed for 2 while being stirred. Subsequently, methanol was separated by filtration, and the precipitate collected by filtration was washed with 3300 parts of water and then dried. Thus, 332 parts of a phenolic hydroxyl group-containing aromatic polyamide resin having a repeating unit represented by the following Formula (12):

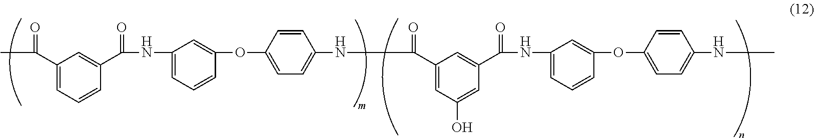

was obtained. 140 parts of γ-butyrolactone was added to 60 parts of the phenolic hydroxyl group-containing aromatic polyamide resin thus obtained, and thus 200 parts of a comparative polyamide resin varnish containing 30% of the phenolic hydroxyl group-containing aromatic polyamide resin was obtained. The number average molecular weight of the comparative polyamide resin was 44,000, and the weight average molecular weight was 106,000. The R value was 1.02.

### Example 1

To 100 parts of a varnish containing 30% of the present polyimide resin (A) obtained in Synthesis Example 1, 16 parts of RE-602S (bisphenol F type epoxy resin, manufactured by Nippon Kayaku Co., Ltd., epoxy equivalent: 188 g/eq) having a melt, viscosity of 0.003 Pa·s as the epoxy resin (C), as well as 4 parts of GPH-65 fused, type novolac resin, manufactured by Nippon. Kayaku Co., Ltd., hydroxyl group equivalent: 200 as an epoxy resin curing agent, 0.3 parts of 2-phenyl-4,5-dihydroxymethylimidazole (2PHZ) as a curing accelerating agent, and 33 parts of γ-butyrolactone as a solvent were respectively added, and the mixture was stirred for 2 hours at 30° C. Thereby, a mixed solution having a total concentration of the polyimide resin (A) and the epoxy resin (C) of 30% was obtained. 45 parts (solid content with respect to the resin: 300%) of boron nitride (manufactured by Mizushima Ferroalloy Co., Ltd., thermal conductivity: 50 W/(m·K)) as a filler (B) was added to 50 of the mixed solution thus obtained, (the total mass of the polyimide resin (A) and the epoxy resin (C) was 15 parts), and the mixture was kneaded with a three-roll. Thus, a varnish of the present Resin Composition (1) was obtained. The relationship between the parts by mass of the polyimide resin (A), the filler (B), and the epoxy resin (C) was such that (A):(C)=65:35 and ((A)+(C)):(B)=25:75.

### Example 2

The same experiment as that of Example 1 was carried out, except that the polyimide resin varnish used was changed to a varnish containing 30% of the polyimide resin (A) obtained in Synthesis Example 2, and thus a varnish of the present Resin Composition (2) was obtained. The relationship between the parts by mass of the polyimide resin (A), the filler (B), and the epoxy resin (C) was such that (A):(C)=65:35 and ((A)+(C)):(B)=25:75.

### Example 3

The same experiment as that of Example 1 was carried out, except that the polyimide resin varnish used was changed to a varnish containing 30% of the polyimide resin (A) obtained in Synthesis Example 3, and thus a varnish of the present Resin Composition (3) was obtained. The relationship between the parts by mass of the polyimide resin (A), the filler (B), and the epoxy resin (C) was such that (A):(C)=65:35 and ((A)+(C)):(B)=25:75.

### Example 4

The same experiment as that of Example 1 was carried out, except that the polyimide resin varnish used was changed to a varnish containing 30% of the polyimide resin (A) obtained in Synthesis Example 4, and thus a varnish of the present Resin Composition (4) was obtained. The relationship between the parts by mass of the polyimide resin (A), the filler (B), and the epoxy resin (C) was such that (A):(C)=65:35 and ((A)+(C)):(B)=25:75.

### Example 5

The same experiment as that of Example 1 was carried out, except that the polyimide resin varnish used was changed to a varnish containing 30% of the polyimide resin (A) obtained in Synthesis Example 5, and thus a varnish of the present. Resin Composition (5) was obtained. The relationship between the parts by mass of the polyimide resin (A), the filler (B), and the epoxy resin (C) was such that (A):(C)=65:35 and ((A)+(C)):(B)=25:75.

### Example 6

The same experiment as that of Example 1 was carried out, except that the polyimide resin varnish used was changed to a varnish, containing 30% of the polyimide resin (A) obtained in Synthesis Example 6, and thus a varnish of the present. Resin Composition (6) was obtained. The relationship between the parts by mass of the polyimide resin (A), the filler (B), and the epoxy resin (C) was such that (A):(C)=65:35 and ((A)+(C)):(B)=25:75.

### Example 7

The same experiment as that of Example 1 was carried out, except that the epoxy resin used was changed to YX4000 skeleton epoxy resin, manufactured by Mitsubishi Chemical Corp., epoxy equivalent: 186 g/eq) having a melt viscosity of 0.02 Pa·s, and thus a varnish of the present Resin Composition (7) was obtained. The relationship between the parts by mass of the polyimide resin (A), the filler (B), and the epoxy resin (C) was such that (A):(C)=65:35 and ((A)+(C)):(B)=25:75.

### Example 8

To 100 parts of a varnish containing 30% of the present polyimide resin (A) obtained in Synthesis Example 1, 30 parts of RE-602S (bisphenol F type epoxy resin, manufactured by Nippon Kayaku Co., Ltd., epoxy equivalent: 188 g/eq) having a melt, viscosity of 0.003 Pa·s as an epoxy resin (C), as well as 5 parts of GPH-65 (biphenylphenol fused, type novolac resin, manufactured by Nippon Kayaku Co., Ltd., hydroxyl group equivalent: 200 g/eq) as an epoxy resin curing agent, 0.4 parts of 2-phenyl-4,5-dihydroxymethylimidazole (2PHZ) as a curing accelerating agent, and 65 parts of γ-butyrolactone as a solvent, were respectively added, and the mixture was stirred for 2 hours at 30° C. Thereby, a mixed solution having a total concentration of the polyimide resin (A) and the epoxy resin (C) of 30% was obtained. 45 parts (solid content with respect to the resin: 300%) of boron nitride (manufactured by Mizushima Ferroalloy Co., Ltd., thermal conductivity: 50 W/(m·K)) as a filler (B) was added to 50 of the mixed solution thus obtained (the total mass of the polyimide resin (A) and the epoxy resin (C) was 15 and the mixture was kneaded with a three-roll. Thus, a varnish of the present Resin Composition (8) was obtained. The relationship between the parts by mass of the polyimide resin (A), the filler (B), and the epoxy resin (C) was such that (A):(C)=50:50 and ((A)+(C)):(B)=25:75.

### Comparative Example 1

The same experiment as that of Example 1 was carried out, except, that the polyimide resin, varnish used, was changed to a varnish containing 30% of the comparative polyimide resin (A) obtained in Synthesis Example 7, in which n=0, and thus a varnish of comparative Resin Composition (9) was obtained. The relationship between the parts by mass of the polyimide resin (A), the filler (B), and the epoxy resin (C) was such, that (A):(C)=65:35 ((A)+(C)):(B)=25:75.

### Comparative Example 2

The same experiment as that of Example 1 was carried out, except that the polyimide resin varnish used was changed to a varnish containing 30% of the comparative polyimide resin (A) obtained in Synthesis Example 8, in which n/m+n=0.17, and thus a varnish of comparative Resin Composition (10) was obtained. The relationship between the parts by mass of the polyimide resin (A), the filler (B), and the epoxy resin (C) was such that (A):(C)=65:35 and ((A)+(C)):(B)=25:75.

### Comparative Example 3

The same experiment as that of Example 1 was carried out, except that the polyimide resin varnish used was changed to a varnish containing 30% of the comparative phenolic hydroxyl group-containing aromatic polyamide resin obtained in Synthesis Example 9, and thus a varnish of comparative Resin Composition (11) was obtained. The relationship between the parts by mass of the polyamide resin (A″), the filler (B), and the epoxy resin (C) was such that (A″):(C)=65:35 and ((A″)+(C)):(B)=25:75.

### Comparative Example 4

To 100 parts of a varnish containing 30% of the comparative phenolic hydroxyl group-containing aromatic polyamide resin obtained in Synthesis Example 9, 3 parts of comparative epoxy resin NC-3000 (biphenyl skeleton-containing novolac type epoxy resin, manufactured by Nippon Kayaku Co., Ltd., epoxy equivalent: 188 g/eq) having a melt viscosity of 0.06 Pa·s as an epoxy resin (C), as well as 0.75 parts of GPH-65 (biphenylphenol fused type novolac resin, manufactured by Nippon Kayaku Co., Ltd., hydroxyl group equivalent: 200 g/eq) as an epoxy resin curing agent, 0.3 parts of 2-phenyl-4,5-dihydroxymethylimidazole (2PHZ) as a curing accelerating agent, and 6 parts of γ-butyrolactone as a solvent were respectively added, and the mixture was stirred for 2 hours at 30° C. Thereby, a mixed solution having a total concentration of the polyamide resin (A″) and the epoxy resin (C) of 30% was obtained. 45 (solid content with respect, to the resin: 300%) of boron nitride (manufactured by Mizushima Ferroalloy Co., Ltd., thermal conductivity: 50 W/(m·K)) as a filler (B) was added, to 50 parts of the mixed solution thus obtained, (the total mass of the polyamide resin (A″) and the epoxy resin (C) was 15 parts), and the mixture was kneaded with a three-roll. Thus, a varnish of comparative Resin Composition (12) was obtained. The relationship between the parts by mass of the polyamide resin (A″), the filler (B), and the epoxy resin (C) was such that (A″):(C)=91:9 and ((A″)+(C)):(B)=25:75.

### Comparative Example 5

The same experiment as that of Example 1 was carried out, except that the epoxy resin used was changed to comparative epoxy resin NC-3000 (biphenyl skeleton-containing novolac type epoxy resin, manufactured by Nippon Kayaku Co., Ltd., epoxy equivalent: 275 g/eq) having a melt, viscosity of 0.06 Pa·s, and thus a varnish of comparative Resin Composition (13) was obtained. The relationship between the parts by mass of the polyimide resin (A), the filler (B), and the epoxy resin (C) was such that (A):(C)=65:35 and ((A)+(C)):(B)=25:75.

### Comparative Example 6

To 100 parts of a varnish containing 30% of the present, polyimide resin (A) obtained in Synthesis Example 4, parts of comparative epoxy resin NC-3000 (biphenyl skeleton containing novolac type epoxy resin, manufactured by Nippon Kayaku Co., Ltd., epoxy equivalent: 275 g/eq) having a melt viscosity of 0.06 Pa·s as an epoxy resin (C), as well as 2 parts of 2-phenyl-4,5-dihydroxymethylimidazole (2PHZ) as a curing accelerating agent, and 2 parts of γ-butyrolactone as a solvent were respectively added, and the mixture was stirred for 2 hours at 30° C. Thereby, a mixed solution having a total concentration of the polyimide resin (A) and the epoxy resin (C) of 30% was obtained. 45 (solid content with respect, to the resin: 300%) of boron nitride (manufactured by Mizushima Ferroalloy Co., Ltd., thermal, conductivity: 50 W/(m·K)) as a filler (B) was added, to 50 parts of the mixed solution thus obtained, (the total mass of the polyimide resin (A) and the epoxy resin (C) was 15 parts), and the mixture was kneaded with a three-roll. Thus, a varnish of comparative Resin Composition (14) was obtained. The relationship between the parts by mass of the polyimide resin (A), the filler (B), and the epoxy resin (C) was such that (A):(C)=95:5 and ((A)+(C)):(B)=25:75.

### Examples 9 to 16

Each of the varnishes of present. Resin Compositions (1) to (8) obtained, in Examples 1 to 8 was applied on a PET film such that the thickness after drying was 150 μm, and the resin composition was dried for 10 minutes at 130° C. to remove the solvent. The film thus obtained was detached from the PET film, and thus the present. Heat-conductive Adhesive Films (1) to (8) were obtained.

### Comparative Examples 7 to 12

Each of the varnishes of comparative Resin compositions (9) to (14) obtained in Comparative Examples 1 to 6 was applied on a PET film such that the thickness after drying was 150 μm, and the resin composition was dried for 10 minutes at 130° C. to remove the solvent. The film thus obtained was detached, from, the PET film, and thus comparative Heat-conductive Adhesive Films (9) to (14) were obtained.

The heat-conductive adhesive films obtained in the various Examples and Comparative Examples were cured, and the electrical insulation properties, heat conductivity, adhesiveness at a low temperature of about 170° C. to 200° C., and the glass transition temperature were measured as follows. The measurement results are presented in Table 1.

### Melt Viscosity of Epoxy Resin

Melt viscosity according to the cone-plate method at 150° C.

Measuring machine: Cone-plate (ICI) high temperature viscometer (manufactured by Research Equipment (London), Ltd.)

Cone No.: 3 (measurement range: 0 to 2.00 Pa·s)

Sample amount: 0.155±0.01 g

### Electrical Insulation Properties

The heat-conductive adhesive films of Examples 9 to 16 and Comparative Examples 7 to 12 were treated for 1 hour at 170° C., and thus cured films were obtained. The cured films thus obtained were treated under the electrical conditions of 30 kV and 10 mA with a dielectric breakdown testing machine (manufactured by Yasuda Seisakusho Co., Ltd.), and thereby the electrical insulation properties were measured.

### Thermal Conductivity (Heat Dissipation Properties)

For each of the heat-conductive adhesive films of Examples 9 to 16 and Comparative Examples 7 to 12, three sheets were stacked and were hot pressed for 60 minutes under the conditions of 180° C. and 1 MPa using a hot plate pressing machine. Thus, a heat-conductive test sample was obtained. The thermal conductivities of the samples thus obtained were measured using a thermal conductivity analyzer (manufactured by Anter Corp., UNITEM Model 2022).

Adhesiveness at Low Temperature (I) (Peel Strength after Lamination with Copper Foil)

Each of the heat-conductive adhesive films of Examples 9 to 16 and Comparative Examples 7 to 12 was sandwiched between two sheets of an electrolytic copper-foil (CF-T9B-HTE, manufactured by Fukuda Metal Foil & Powder Co., Ltd.) having a thickness of 18 μm such that the rough surfaces were arranged to face the heat-conductive adhesive film side. The assembly was hot pressed for 60 under the conditions of 180° C. and 1 MPa using a hot plate pressing machine, and thus a sample for adhesion test was obtained. For each of these samples, a specimen having a width of 1 cm was torn off in the direction of 90° (±5°) according to JIS C6481 using a Tensilon tester (manufactured by Toyo Baldwin Co., Ltd.) by setting the tear-off rate to 3 mm/min. Thus, the adhesiveness at a low temperature (I) of the adhesive film, (peel strength after lamination with copper foil) was measured.

Adhesiveness at Low Temperature (II) (Tensile Shear Adhesive Strength after Lamination with Aluminum, Plate)

According to JIS K 6850-1999, two sheets of aluminum plates as metal adherends and each of the heat-conductive adhesive films of Examples 9 to 16 and Comparative Examples 7 to 12 as an adhesive layer were hot pressed for 60 under the conditions 180° C. and 1 MPa using a hot plate pressing machine, and thus a sample for a tensile shear adhesive test, was obtained. For such a sample, the adhesiveness at a low temperature (II) (tensile shear adhesive strength) of the adhesive film was measured according to JIS K 6850-1999 using a Tensilon tester (manufactured by Toyo Baldwin Co., Ltd.), by setting the tensile rate to 50 mm/second. As the temperature at the time of pulling, the measurement was carried out under two conditions such as room temperature and 175° C.

### Glass Transition Temperature

Each of the heat-conductive adhesive films of Examples 9 to 16 and Comparative Examples 7 to 12 was treated for 1 hour at 170° C., and thus a cured film was obtained. The DMA of the cured film thus obtained was measured (using EXSTAR DMS6100 manufactured by Seiko Instruments, Inc.), and tan δmax was measured as the glass transition temperature. Furthermore, apart from this, a varnish of each of the polyimide resins of Synthesis Examples 1 to 9 was applied on a PET film such, that the thickness after drying was 25 μm, and the resin varnish was dried for 10 minutes at 130° C. to remove the solvent, and then heating was performed for another 1 hour at 170° C. Thus a film was obtained. The DMA of the film thus obtained was measured (using EXSTAR DMS6100 manufactured by Seiko Instruments, Inc.), and tan δmax was measured as the glass transition temperature.

TABLE 1

| | | | | | | | | | Evaluation results | | | | | |
|---|---|---|---|---|---|---|---|---|---|---|---|---|---|---|
| | | | | | | | | | | | | | Adhesiveness | |
| | | | | | | | | | | | | | at low | Adhesiveness |
| Heat- | | Polyimide resin (A) | | | | Epoxy resin (C) | | | Electrical | | Adhesiveness | Glass | temperature | at low |
| conductive | | | | | Glass | | Melt | Mass | insulation | Thermal | at low | transition | (II) (room | temperature |
| adhesive | Resin | | | | transition | | viscosity | ratio of | properties | conductivity | temperature | temperature | temperature) | (II) (175° C.) |
| film | composition | — | Diaminophenol | n/(m + n) | point ° C. | Name | Pa · s | (A):(C) | kV | W/m · K | (I) N/cm | ° C. | MPa | MPa |
| Example 9 | Example 1 | Synthesis | ABPS | 0.016 | 188 | RE602 | 0.003 | 65:35 | 6.0 | 13.0 | 6.2 | 202 | 9.4 | 8.5 |
| | | Example 1 | | | | | | | | | | | | |
| Example 10 | Example 2 | Synthesis | ABPS | 0.021 | 190 | RE602 | 0.003 | 65:35 | 5.9 | 12.4 | 5.3 | 206 | 8.9 | 8.2 |
| | | Example 2 | | | | | | | | | | | | |
| Example 11 | Example 3 | Synthesis | ABPS | 0.031 | 195 | RE602 | 0.003 | 65:35 | 5.9 | 12.3 | 5.8 | 215 | 9.8 | 8.0 |
| | | Example 3 | | | | | | | | | | | | |
| Example 12 | Example 4 | Synthesis | ABPS | 0.04 | 205 | RE602 | 0.003 | 65:35 | 6.0 | 12.4 | 5.5 | 218 | 9.3 | 7.8 |
| | | Example 4 | | | | | | | | | | | | |
| Example 13 | Example 5 | Synthesis | BAFA | 0.021 | 191 | RE602 | 0.003 | 65:35 | 5.9 | 13.2 | 5.9 | 205 | 9.3 | 8.6 |
| | | Example 5 | | | | | | | | | | | | |
| Example 14 | Example 6 | Synthesis | HAB | 0.021 | 193 | RE602 | 0.003 | 65:35 | 6.2 | 12.9 | 6.1 | 212 | 9.1 | 7.6 |
| | | Example 6 | | | | | | | | | | | | |
| Example 15 | Example 7 | Synthesis | ABPS | 0.016 | 188 | YX4000 | 0.02 | 65:35 | 5.8 | 12.7 | 6.3 | 210 | 9.3 | 8.6 |
| | | Example 1 | | | | | | | | | | | | |
| Example 16 | Example 8 | Synthesis | ABPS | 0.04 | 205 | RE602 | 0.003 | 50:50 | 6.0 | 12.9 | 6.0 | 209 | 9.5 | 8.4 |
| | | Example 4 | | | | | | | | | | | | |
| Comparative | Comparative | Synthesis | None | 0 | 185 | RE602 | 0.003 | 65:35 | 6.1 | 12.6 | 6.1 | 165 | 8.7 | 8.1 |
| Example 7 | Example 1 | Example 7 | | | | | | | | | | | | |
| Comparative | Comparative | Synthesis | ABPS | 0.17 | 210 | RE602 | 0.003 | 65:35 | 3.0 | 10.8 | 5.8 | 230 | 9.0 | 7.6 |
| Example 8 | Example 2 | Example 8 | | | | | | | | | | | | |
| Comparative | Comparative | Synthesis | (*1) | (*1) | 270 | RE602 | 0.003 | 65:35 | 3.5 | 8.0 | 5.2 | 220 | 11.2 | 3.6 |
| Example 9 | Example 3 | Example 9 | | | | | | (2*) | | | | | | |
| Comparative | Comparative | Synthesis | (*1) | (*1) | 270 | NC- | 0.06 | 91:9 | 3.3 | 7.5 | 4.8 | 236 | 10.9 | 3.9 |
| Example 10 | Example 4 | Example 9 | | | | 3000 | | (*2) | | | | | | |
| Comparative | Comparative | Synthesis | ABPS | 0.016 | 188 | NC- | 0.06 | 65:35 | 3.8 | 8.5 | 4.2 | 210 | 6.2 | 5.6 |
| Example 11 | Example 5 | Example 1 | | | | 3000 | | | | | | | | |
| Comparative | Comparative | Synthesis | ABPS | 0.04 | 205 | NC- | 0.06 | 95:5 | 3.2 | 8.0 | 4.1 | 223 | 6.6 | 5.5 |
| Example 12 | Example 6 | Example 4 | | | | 3000 | | | | | | | | |

(*1): An aromatic polyamide resin was used in Synthesis Example 9.
(*2): The mass ratio (A″):(C) was used in Comparative Examples 3 and 4.

As can be seen from Table 1, in Examples 9 to 16 in which heat-conductive adhesive films using the present resin compositions, the electrical insulation properties were about 6 kV, the thermal conductivity was 12 W/(m·K) or higher, the adhesiveness at a low temperature (I) (peel strength after lamination with copper foil) was about 6 the adhesiveness at a low temperature (II) (tensile shear adhesive strength after lamination with an aluminum plate) was about 9 MPa when the adhesiveness was measured at room temperature, the adhesiveness at a low temperature (II) was about 8 MPa when the adhesiveness was measured at 175° C., and the glass transition temperature was 200° C. or higher. Thus, these Examples succeeded in achieving the goals.

On the contrary, in Comparative Examples 7 to 12, the goal was not achieved in any one or more of these characteristic values. This will be explained in detail below. First, regarding the polyimide resin, resin compositions having different phenolic hydroxyl group contents were compared. Comparative Example 7 is a polyimide resin composition without phenolic hydroxyl groups, and Comparative Example 8 is a polyimide resin composition with a large phenolic hydroxyl group content. When these Comparative Examples 7 and 8 were compared with Examples 9 to 12, the glass transition temperature was as low as 165° C. in Comparative Example 7, and the goal value was not attained, while in Examples 9 to 12 of the present invention, the glass transition temperature was 200° C. or higher, and the goal values were attained. In regard to the electrical insulation properties, dielectric breakdown occurred at 3.0 kV in Comparative Example 8, while dielectric breakdown did not occur up to about 6 kV in Examples 9 to 12 of the present invention.

Next, a comparison was made between resin compositions having different melt viscosities of the epoxy resins. When Comparative Example 11 and Comparative Example 12 (Patent Literature 3) in which epoxy resins having high melt viscosities were used were compared with Example 9 and Example 15 of the present invention in which epoxy resins having low melt viscosities were used, in regard to the electrical insulation properties, dielectric breakdown occurred at a low voltage such as 3.8 kV in Comparative Example 11, and dielectric breakdown occurred at 3.2 kV in Comparative Example 12. However, dielectric breakdown did not occur up to 6.0 kV in Example 9 of the present, invention, and dielectric breakdown did not occur-up to 5.8 kV in Example 15. Furthermore, the heat conductivity was 8.5 W/(m·K) in Comparative Example 11, and the heat conductivity was 8.0 W/(m·K) in Comparative Example 12. However, the heat conductivity had a high value of 13 W/(m·K) in Example 9 of the present invention, and 12.7 W/(m·K) in Example 15. Furthermore, the adhesiveness at a low temperature (I) (peel strength after lamination with copper foil) was only 4.2 N/cm in Comparative Example 11 and 4.1 N/cm in Comparative Example 12. However, the adhesiveness at a low temperature (I) exhibited a high value of 6.2 N/cm in Example 9 and 6.3 in Example 15.

Furthermore, also in a comparison between the phenolic hydroxyl group-containing polyamides (Patent Literature 2) in Comparative Example 9 and Comparative Example 10, and the phenolic, hydroxyl group-containing polyimides of Examples 9 to 16 of the present, invention, which is a comparison of composition having different resin skeletons, in regard to the electrical insulation properties, dielectric breakdown occurred at 3.5 kV in Comparative Example 9 (resin composition of Example 2 of Patent Literature 2) and at 3.3 kV in Comparative Example 10. However, in Examples 9 to 16, dielectric breakdown did not occur up to about 6.0 kV. Furthermore, also regarding the thermal conductivity, the values were only 8 W/(m·K) in Comparative Example 9 and 7.5 W/(m·K) in Comparative Example 10. However, in Examples 9 to 16 of the present, invention, the thermal conductivity exhibited high values such as 12 W/(m·K) or higher. In regard to the adhesiveness at a low temperature (II) (tensile shear-adhesive strength after lamination with an aluminum plate), the adhesiveness values were only 3.6 MPa and 3.9 MPa in the measurement at 175° C. of Comparative Example 9 and Comparative Example 10, respectively; however, in Examples 9 to 16 of the present invention, the adhesiveness exhibited high values such as about 8 MPa.

Furthermore, it can be seen from this Table 1 that in regard to the resin compositions using polyamide resins, the effect on the properties of the resin composition caused by the difference in the melt viscosities of the epoxy resins was not acknowledged; however, in the aromatic polyimide resin compositions containing phenolic hydroxyl groups, the significant effect in the case of using an epoxy resin having a low melt viscosity against the case of using an epoxy resin having a high melt viscosity was recognized. That is, Comparative Examples 9 and 10 were resin composition using polyamide resins, and Comparative Example 9 corresponded to the case in which an epoxy resin having a low melt viscosity was used, while Comparative Example 10 corresponded to the case in which an epoxy resin having a high melt viscosity was used. When the two were compared, regarding the voltage at which dielectric breakdown occurred in connection with electrical insulation properties, the voltage was 3.5 kV in Comparative Example 9 and 3.3 kV in Comparative Example 10, and thus the difference between the two was only 0.2 kV. Also, for thermal conductivity, the value was 8 W/(m·K) in Comparative Example 9 and 7.5 W/(m·K) in Comparative Example 10, and the difference between the two was only 0.5 W/(m·K), which was not a large difference. That is, the melt viscosity of the epoxy resin used in the resin composition using a polyamide resin does not affect the electrical insulation properties and thermal conductivity. However, in regard to the aromatic polyimide resin composition containing phenolic hydroxyl groups, as can be seen from a comparison of Examples 9 and 15 with Comparative Example 11, in Comparative Example 11 in which an epoxy resin having a high melt viscosity was used, dielectric breakdown occurred at a low voltage such as 3.8 in connection with the electrical insulation properties, and the thermal conductivity was only 8.5 W/(m·K). On the contrary, in Example 9 of the present invention in which an epoxy resin having a low melt viscosity was used, dielectric breakdown did not occur up to a high voltage such as 6.0 kV (5.8 kV in Example 14) in connection with the electrical insulation properties, and the thermal conductivity also exhibited a high value of 13 W/(m·K) (12.7 W/(m·K) in Example 15). Therefore, in an aromatic polyimide resin composition containing phenolic hydroxyl groups, significantly high effects were exhibited in a case in which an epoxy resin having a low melt viscosity was used, as compared to the case in which an epoxy resin having a high melt viscosity was used.

Furthermore, it can be seen from this Table 1 that when an epoxy resin having a low melt viscosity is used, the kind of the epoxy resin is not affected. That is, in regard to Examples 9 and 15 in which different kinds of the epoxy resin having a low melt viscosity were used, dielectric breakdown did not occur up to 6.0 kV in Example 9, and was up to 5.8 kV in Example 15 in connection with the electrical insulation properties. Furthermore, the thermal conductivity was 13 W/(m·K) in Example 9 and was 12.7 W/(m·K) in Example 15. Furthermore, the adhesiveness at a low temperature (I) (peel strength after lamination with copper foil) was also 6.2 N/cm in Example 9 of the present invention, and was 6.3 N/cm in Example 15. All of these properties exhibited high values to an equal extent, irrespective of the kind of the epoxy resin.

1. (canceled)

2. A resin composition comprising an aromatic polyimide resin (A) containing phenolic hydroxyl groups, the aromatic polyimide resin (A) having a repeating unit represented by the following Formula (1): 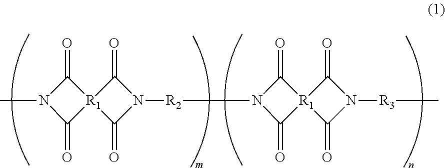
wherein m and n are average values and represent positive numbers satisfying the relationships: 0.005<n/(m+n)<0.14 and 0<m+n<200; R₁ represents a tetravalent aromatic group having an ether bond but not having a phenolic hydroxyl group; R₂ represents a divalent aromatic group containing an ether bond but not having a phenolic hydroxyl group; and R₃ represents a divalent aromatic group having a phenolic hydroxyl group,
a filler (B), and an epoxy resin (C) having a melt viscosity of 0.04 Pa·s or less,
wherein the ratio of the amounts in parts by mass of the polyimide resin (A), the filler (B), and the epoxy resin (C) satisfies the relationships: (A):(C)=99:1 to 1:99 and ((A)+(C)):(B)=80:20 to 5:95.

3. The resin composition according to claim 2, wherein in the repeating unit represented by Formula (1),
R₁ represents a tetravalent aromatic group represented by the following Formula (2): 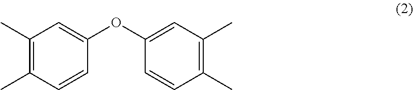
R₂ represents a divalent aromatic group represented by the following Formula (3): 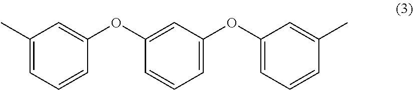
and R₃ represents one or more divalent aromatic groups selected from the following Formula (4):

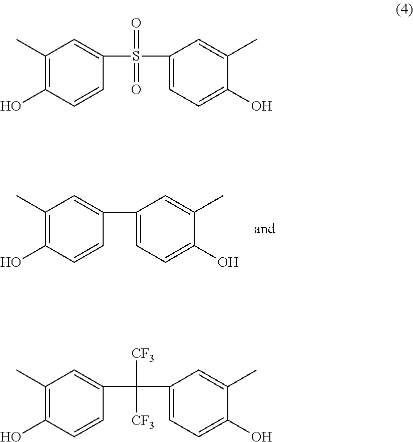 [SMILES: Cc1cc(S(=O)(=O)c2ccc(O)c(C)c2)ccc1O ; Cc1cc(-c2ccc(O)c(C)c2)ccc1O ; Cc1cc(C(c2ccc(O)c(C)c2)(C(F)(F)F)C(F)(F)F)ccc1O]

4. The resin composition according to claim 2, wherein the filler (B) is at least one selected from aluminum nitride and boron nitride.

5. A varnish comprising the resin composition according to claim 2 dissolved in an organic solvent.

6. A heat-conductive adhesive film comprising the resin composition according to claim 2.

7. A laminate comprising the heat-conductive adhesive film according to claim 6 and a copper foil, an aluminum foil or a stainless steel foil.

8. A laminate comprising the heat-conductive adhesive film according to claim 6 and a heat dissipation plate.

9. A laminate comprising a cured layer of the resin composition according to claim 2 and a copper foil, an aluminum foil or a stainless steel foil.

10. A laminate comprising a cured layer of the resin composition according to claim 2 and a heat dissipation plate.

11. An electronic component comprising a cured layer of the resin composition according to claim 2.

12. The electronic component according to claim 11, wherein the cured layer of the resin composition exists between a power module and a cooler in a state of being in contact with both of the elements.

13. The electronic component according to claim 12, wherein the power module is a silicon carbide-based power module.

14. A phenolic hydroxyl group-containing aromatic polyimide resin (A1) comprising in the structure a repeating unit represented by the following Formula (9): 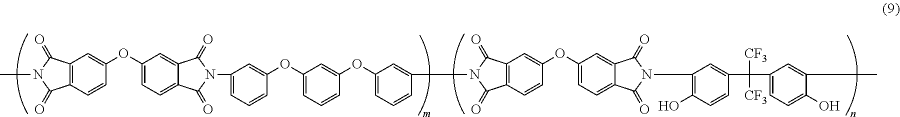
or Formula (10): 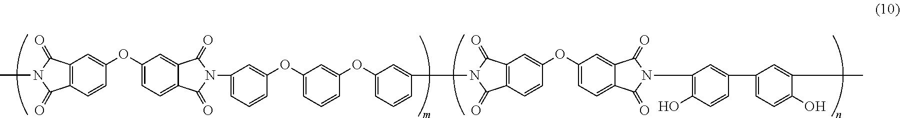
wherein m and n are average values and represent positive numbers satisfying the relationships: 0.005<n/(m+n)<0.14 and 0<m+n<200.
